(19) United States
(12) Patent Application Publication
(10) Pub. No.: US 2024/0413808 A1
(43) Pub. Date: Dec. 12, 2024

(54) POLARIZATION-INVERTED HIGHER-ORDER PLATE-MODE RESONATORS AND METHODS FOR MAKING THE SAME

(71) Applicant: RF360 Singapore Pte. Ltd., Singapore (SG)

(72) Inventors: Constantin WALENTA, Unterschleißheim (DE); Soeren ZIMMERMANN, München (DE); Willi AIGNER, Moosinning (DE)

(21) Appl. No.: 18/333,179

(22) Filed: Jun. 12, 2023

(51) Int. Cl. H03H 9/17; H03H 3/02; H03H 9/13

(52) U.S. Cl. CPC H03H 9/176; H03H 3/02; H03H 9/132; H03H 9/173; H03H 2003/021

(57) ABSTRACT

Disclosed are polarization-inverted higher-order plate-mode resonators and methods for making the same. In an aspect, a plate-mode resonator includes a first piezoelectric layer having a first crystal orientation specified by a first set of Euler angles α₁, β₁, and γ₁, a dielectric layer disposed on a top surface of the first piezoelectric layer, a second piezoelectric layer, disposed on a top surface of the dielectric layer, having a second crystal orientation specified by a second set of Euler angles α₂, β₂, and γ₂, wherein az is approximately equal to α₁, wherein a difference between β₂ and β₁ is approximately 180 degrees, and wherein γ₂ is approximately equal to γ₁, and a metallization structure disposed on a top surface of the second piezoelectric layer, the metallization structure comprising at least one interdigital transducer.

### BACKGROUND OF THE DISCLOSURE

### 1. Field of the Disclosure

Aspects of the disclosure relate generally to microacoustic wave filters, and more specifically but not exclusively, to polarization-inverted higher-order plate-mode resonators.

### 2. Description of the Related Art

Surface acoustic wave (SAW) and bulk acoustic wave (BAW) filters are devices which make use of the properties of piezoelectric material to convert electrical signals to microacoustic waves and back to electrical signals, and are thus commonly referred to as “microacoustic devices” or “microacoustic wave devices.” The dimensions of the microacoustic device can be tuned such that specific frequencies are allowed or blocked, making microacoustic devices ideal radio frequency (RF) filters.

FIG. 1A is an isometric view of a conventional, solidly-mounted plate-mode resonator 100, i.e., where the piezoelectric material is mounted atop a dielectric acoustic mirror that separates the piezoelectric layer from the carrier. FIG. 1A shows an interdigital transducer (IDT) which consists of two interlocking comb-shaped arrays of metallic electrodes whose function is to convert electric signals to microacoustic plate modes by generating periodically distributed mechanical forces via piezoelectric effect, or to convert the microacoustic plate modes back to electrical signals. The solidly-mounted plate resonator 100 has mechanical stability, which allows the piezoelectric layer to be very thin and allows for thermal management since heat can be dissipated through the carrier. However, the solidly-mounted design requires multilayer processing to create the acoustic mirror and limits the performance (e.g., values of resonance quality factor Q and of the electro-mechanical coupling coefficient k²) of the resonator.

FIG. 1B is an isometric view of a conventional, suspended configuration plate-mode resonator 102. The plate-mode resonator 102 is not solidly-mounted to the carrier but instead is separated from the carrier by a cavity, such as an air gap. The suspended configuration plate-mode resonator 102 provides higher Q factors and enhanced electromechanical coupling when compared to the solidly-mounted plate-mode resonator 100 and does not require multilayer processing, but the challenges include large area suspended thin film piezoelectric layers, power durability, and relative fragility compared to solidly-mounted designs.

Moreover, there is a need for very high frequency resonators, e.g., >10 GHz, for fifth generation (5G) and sixth generation (6G) telecommunications. High frequencies are hard to achieve with conventional SAW or thin-film SAW (TFSAW) designs: very narrow finger electrode separations (<100 nm) are required, which are out of reach for established and cost-efficient lithographical tools, and which create parasitic effects on resonance quality factors and power durability. These factors make >10 GHz SAW/TFSAW designs challenging to manufacture and challenging to meet power handling requirements. High frequencies are also challenging to achieve with conventional BAW concepts: very thin piezoelectric plates are required, and variations in plate thickness significantly affect resonance frequencies, which makes the performance of the BAW very sensitive to wafer process variations. Moreover, ultrathin acoustic mirror thicknesses are needed, and mirror reflectivity is likewise very sensitive to thickness variations.

Thus, there is a need for an improved plate-mode resonator, circumventing the disadvantages above and offering more degrees of freedom regarding designs towards desired higher Q factors and enhanced electromechanical coupling.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a plate-mode resonator includes a first piezoelectric layer having a first crystal orientation specified by a first set of Euler angles α₁, β₁, and γ₁, a dielectric layer disposed on a top surface of the first piezoelectric layer, a second piezoelectric layer, disposed on a top surface of the dielectric layer, having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁, and a metallization structure disposed on a top surface of the second piezoelectric layer, the metallization structure comprising at least one interdigital transducer. When used in reference to differences in Euler angles, the term “approximately” reflects the fact that manufacturing tolerances may be within a few degrees or within a fraction of a degree. Thus, to say that that a Euler angle is approximately N degrees also covers embodiments where the Euler angle in question is N degrees, plus or minus M degrees, where M is the manufacturing tolerance, e.g., +/−10 degrees, +/−3 degrees, etc. Likewise, to say that the difference between two Euler angles is approximately 180 degrees also covers embodiments where the difference is 180 degrees, plus or minus M degrees, e.g., between 170 and 190 degrees for a +/−10-degree manufacturing tolerance, or between 177 and 183 degrees for a +/−3-degree manufacturing tolerance, etc.

In an aspect, a method for fabricating a plate-mode resonator includes providing a first piezoelectric layer having a first crystal orientation specified by a first set of Euler angles α₁, β₁, and γ₁, forming a dielectric layer on a top surface of the first piezoelectric layer, providing a second piezoelectric layer on a top surface of the dielectric layer, the second piezoelectric layer having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁, and forming a metallization structure on a top surface of the second piezoelectric layer, the metallization structure comprising at least one interdigital transducer.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1A and FIG. 1B are isometric views of conventional plate-mode resonators.

FIG. 2A is a cross-sectional view of a portion of a conventional plate-mode resonator.

FIG. 2B is a plot showing simulated admittance versus frequency of the conventional plate-mode resonator.

FIG. 3A is a cross-sectional view of a portion of a plate-mode resonator according to aspects of the disclosure.

FIG. 3B is a plot showing simulated admittance versus frequency of the plate-mode resonator according to aspects of the disclosure.

FIG. 4A through FIG. 4F illustrate portions of a wafer process for fabricating a plate-mode resonator according to aspects of the disclosure.

FIG. 5 is a flowchart of an example process 500 for fabricating a polarization-inverted higher-order plate-mode resonator, according to aspects of the disclosure.

FIG. 6 illustrates an exemplary mobile device in accordance with one or more aspects of the disclosure.

FIG. 7 illustrates various electronic devices that may be integrated with any of the aforementioned integrated device or semiconductor device in accordance with one or more aspects of the disclosure.

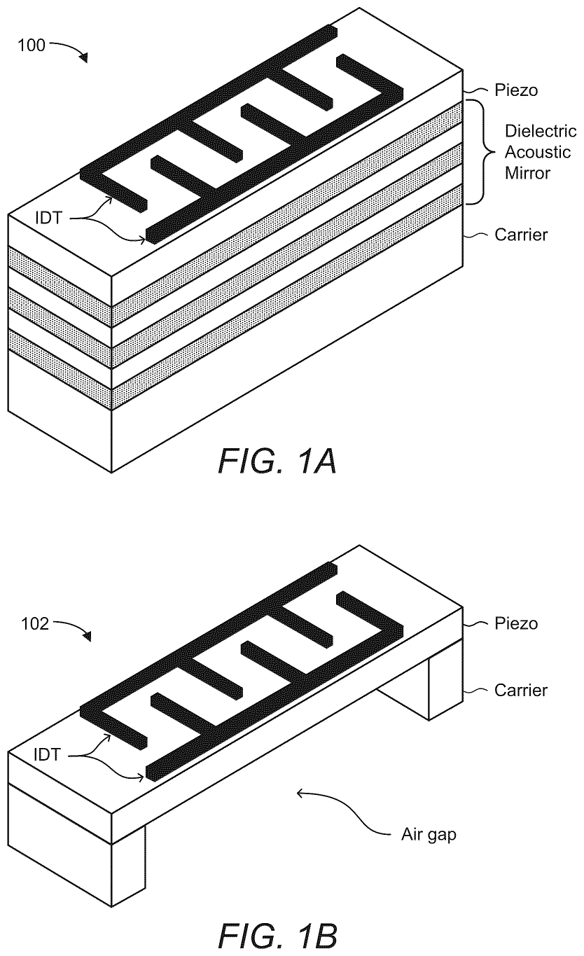

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are polarization-inverted higher-order plate-mode resonators and methods for making the same. In an aspect, a plate-mode resonator includes a first piezoelectric layer having a first crystal orientation specified by a first set of Euler angles α₁, β₁, and γ₁, a dielectric layer disposed on a top surface of the first piezoelectric layer, a second piezoelectric layer, disposed on a top surface of the dielectric layer, having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁, and a metallization structure disposed on a top surface of the second piezoelectric layer, the metallization structure comprising at least one interdigital transducer.

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a plate-mode resonator includes a first piezoelectric layer having a first crystal orientation specified by a first set of Euler angles α₁, β₁, and γ₁, a dielectric layer disposed on a top surface of the first piezoelectric layer, a second piezoelectric layer, disposed on a top surface of the dielectric layer, having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁, and a metallization structure disposed on a top surface of the second piezoelectric layer, the metallization structure comprising at least one interdigital transducer.

In an aspect, a method for fabricating a plate-mode resonator includes providing a first piezoelectric layer having a first crystal orientation specified by a first set of Euler angles α₁, β₁, and γ₁, forming a dielectric layer on a top surface of the first piezoelectric layer, providing a second piezoelectric layer on a top surface of the dielectric layer, the second piezoelectric layer having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁, and forming a metallization structure on a top surface of the second piezoelectric layer, the metallization structure comprising at least one interdigital transducer.

Other objects and advantages associated with the aspects disclosed herein will be apparent to those skilled in the art based on the accompanying drawings and detailed description.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

With ongoing demands towards higher radio frequency filter solutions, established microacoustic devices face significant scaling challenges. This already applies to the emerging fifth-generation (5G) New Radio (NR) bands predominantly assigned to sub-6 GHz target frequencies. Even higher frequencies above 10 GHz are currently under consideration to be implemented within the sixth generation (6G) mobile system standard. The latter require either electrode separations out of range for cost-efficient lithographical processing in surface acoustic wave approaches, or ultra-thin piezoelectric layers with associated high sensitivities in performance in bulk acoustic wave technology. As such, innovative approaches are needed to face the current and future challenges.

A laterally-excited higher-order plate-mode resonator featuring polarization-inverted piezoelectric plates encapsulating a temperature-compensating dielectric layer is disclosed herein. Significant advantages of this configuration, when compared to a conventional single-layer laterally-excited plate-mode resonator, include the following:
High frequencies can be obtained with thicker piezoelectric plates, significantly enhancing the mechanical stability of freely suspended plate-mode resonators operating at high frequencies.
By inverting the polarization of the piezoelectric plates, i.e., by choosing angles for the piezoelectric plates with a 180° shift, meaning direct opposite orientations in Euler angles, the fundamental mode can be suppressed.
Although the mode is of higher order in the proposed plate-mode resonator, there is no unwanted fundamental mode. This strongly excited fundamental mode in single-layer piezoelectric plate-mode resonators might be critical for filter design and its suppression might be extremely challenging or not feasible at all.
The dielectric material involved allows to tune/reduce spurious mode excitation.
The dielectric material involved allows to improve/adjust the resonance frequency shift upon temperature variation.

The structures presented herein enable a laterally-excited plate-mode resonator with moderate thicknesses for very high frequency resonators (>10 GHz). The inclusion of an intermediate dielectric layer such as, but not limited to, SiO₂ enables suppression of unwanted modes and temperature coefficient of frequency (TCF) tuning. Moreover, these structures can be realized using currently available wafer process technology.

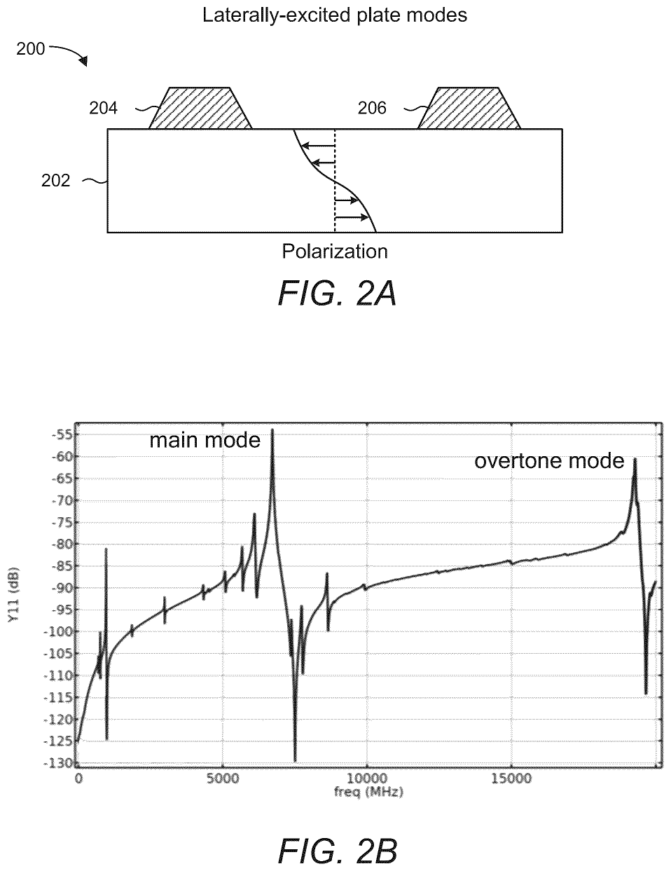

FIG. 2A is a cross-sectional view of a portion of a conventional plate-mode resonator 200 (which may be referred to herein simply as “the conventional resonator 200”). FIG. 2A shows the cross-sectional view of a piezoelectric layer 202, one of the metal IDT electrodes 204, and another of the metal IDT electrodes 206. The piezoelectric layer 202 is a lithium niobate (LN) crystal. The polarization shown in this figure is a feature of the excited plate mode, i.e., the local displacement direction of the acoustic mode.

FIG. 2B is a plot showing simulated admittance versus frequency of the conventional resonator 200, which has a main mode resonance frequency of about 6.7 GHz and an overtone mode resonance frequency of about 19 GHz (with significantly lower coupling than the main mode), but also many unwanted mode resonant frequencies typically exhibited by membrane-type plate-mode resonators. Moreover, the conventional resonator 200 has a thermal coefficient of frequency (TCF) that is dominated by the intrinsic TCF of the piezoelectric plate.

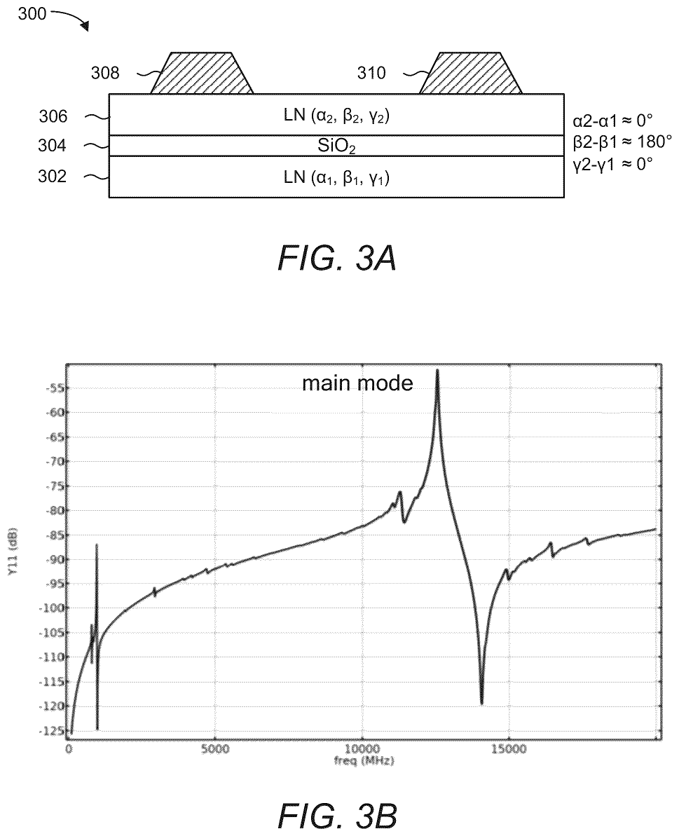

FIG. 3A is a cross-sectional view of a portion of a polarization-inverted higher-order plate-mode resonator 300 (which may be referred to herein simply as “the resonator 300”) according to aspects of the disclosure. The resonator 300 is a symmetric plate mode membrane-type plate-mode resonator with an inverted LN layer. In the example shown in FIG. 3A, the resonator 300 comprises a first piezoelectric layer 302 having a first crystal orientation specified by a first set of Euler angles α₁, β₁, and γ₁, a dielectric layer 304 disposed on a top surface of the first piezoelectric layer, and a second piezoelectric layer 306, disposed on a top surface of the dielectric layer, having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁. For brevity of description, a set of Euler angles αₙ, βₙ, and γₙ will be represented as a triplet of numbers, e.g., (αₙ, βₙ, and γₙ).

For example, in some aspects, the second piezoelectric layer 306 is a “z-cut” crystal (i.e., having a crystal orientation (90, 0, 0) or (0, 0, 90)) and the first piezoelectric layer 302 is an “inverted z-cut” crystal (i.e., having a crystal orientation (90, −180, 0) or (0, −180, 90)). In other aspects, the first and second piezoelectric layers may have other pairs of crystal orientations, such as β₁=38 and β₂=−142, or β₁=32 and β₂=−148, to give two examples. The example orientations described herein are illustrative and not limiting.

It is noted that in some instances a particular crystal orientation may be denoted by more than one triplet of Euler angles. For example, the Euler triplet (90, 0, 0) and the Euler triplet (0, 0, 90) result in the same crystal orientation. Therefore, for brevity of description, when a particular orientation is specified by a Euler triplet, it will be understood that all other Euler triplets that result in the same crystal orientation are also explicitly contemplated.

In the example illustrated in FIG. 3A, metal IDT electrodes 308 and 310 are disposed on the top surface of the second piezoelectric layer 306. In the example shown in FIG. 3A, the dielectric layer 304 comprises an SiO₂ layer, but other materials, such as Si₃N₄, etc., may be alternatively or additionally used. In some aspects, at least one of the first piezoelectric layer 302 and the second piezoelectric layer 306 comprises lithium niobate or lithium tantalate.

FIG. 3B is a plot showing simulated admittance versus frequency of the resonator 300 according to aspects of the disclosure. The resonator 300 has a main mode resonance frequency of about 13 GHz, which is about twice the main mode resonance frequency of the conventional resonator 200. Moreover, the resonator 300 will have a thicker membrane compared to the thickness of the conventional resonator 200 design for the same frequency. For example, the resonator 300 design can be more than twice as thick as the conventional resonator 200 and resonate at the same frequency. This makes the resonator 300 less fragile than the conventional resonator 200. Also, the resonator 300 exhibits fewer unwanted modes as compared to the conventional resonator 200 and has an improved TCF compared to the conventional resonator 200. Another advantage of the resonator 300 is that its resonant frequency can be further tuned by adjusting the thickness of the dielectric layer 304.

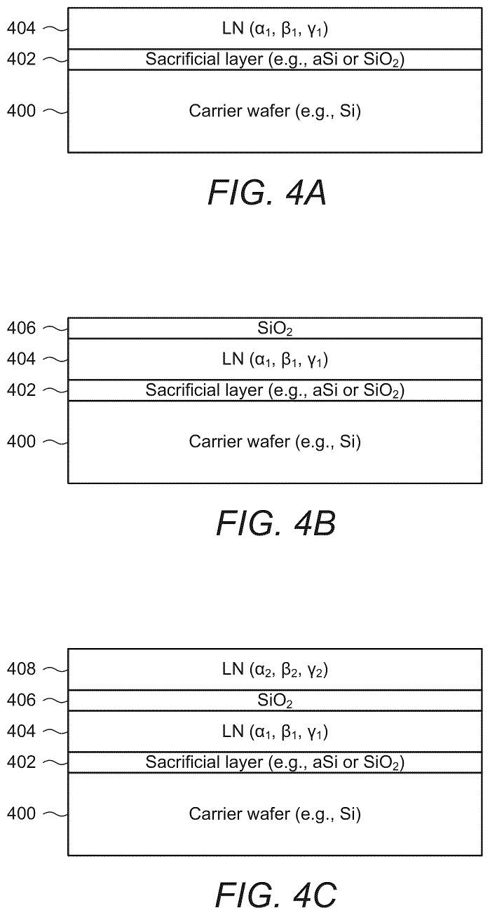

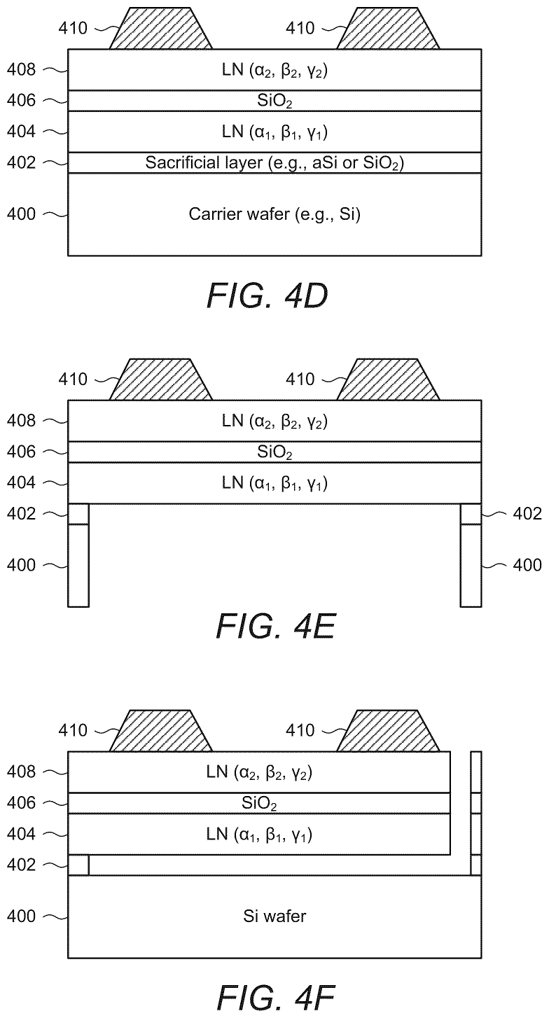

FIG. 4A through FIG. 4F illustrate portions of a wafer process for fabricating a plate-mode resonator according to aspects of the disclosure. FIG. 4A illustrates a thin film wafer stack comprising a carrier wafer 400 (e.g., silicon) upon which has been fabricated a sacrificial layer 402, e.g., amorphous silicon (aSi) or SiO₂, to which a first piezoelectric layer 404 has been bonded and polished down to a target thickness.

FIG. 4B illustrates the result after deposition of a dielectric layer 406 (e.g., SiO₂), which acts as a temperature compensating layer in the final resonator.

FIG. 4C illustrates the result after a second piezoelectric layer 408 has been bonded to the dielectric layer 406. In some aspects, the thickness of the second piezoelectric layer 408 is adjusted via grinding and polishing. The first piezoelectric layer 404 has a first crystal orientation specified by a first set of Euler angles α₁, β₁, and γ₁, and the second piezoelectric layer has a second crystal orientation specified by a second set of Euler angles α₂, β₂, and γ₂, where α₂ is approximately equal to α₁, a difference between β₂ and β₁ is approximately 180 degrees, and γ₂ is approximately equal to γ₁. Another way to describe the relative crystal orientations of the first piezoelectric layer 404 and the second piezoelectric layer 408 is that the second crystal orientation is rotated 180° along an axis parallel to the surface of the piezoelectric and dielectric layers compared to the first crystal orientation. In some aspects, the first piezoelectric layer 404 has a first polarization angle, and the second piezoelectric layer 408 has a second polarization angle that is an opposite direction from the first polarization angle.

In some aspects, the first piezoelectric layer 404 is an inverted z-cut layer and the second piezoelectric layer 408 is a z-cut layer, but other different orientations of the first piezoelectric layer 404 relative to the second piezoelectric layer 408 may also be used provided that |β₂−β₁| is approximately 180 degrees. When used in reference to differences in Euler angles, the term “approximately” reflects the fact that the difference between β₂ and β₁ may not be exactly 180 degrees, that α₂ may not be exactly α₁, and that γ₂ may not be exactly γ₁. Actual manufacturing tolerances may be within a few degrees or within a fraction of a degree, for example.

FIG. 4D illustrates the result after deposition of the IDTs 410, which are finger electrode structures tailored to excite the plate-modes.

FIG. 4E illustrates one variant in which the sacrificial layer 402 is removed within the device area to produce a freely-suspended resonator configuration. In some aspects, some or all of the carrier wafer 400 may also be removed. In some aspects, the backside opening may be produced using deep reactive ion etching (DRIE).

FIG. 4F illustrates another variant in which the sacrificial layer 402 is removed, e.g., using xenon difluoride (XeF₂) cavity release etching, to produce a freely-suspended resonator configuration.

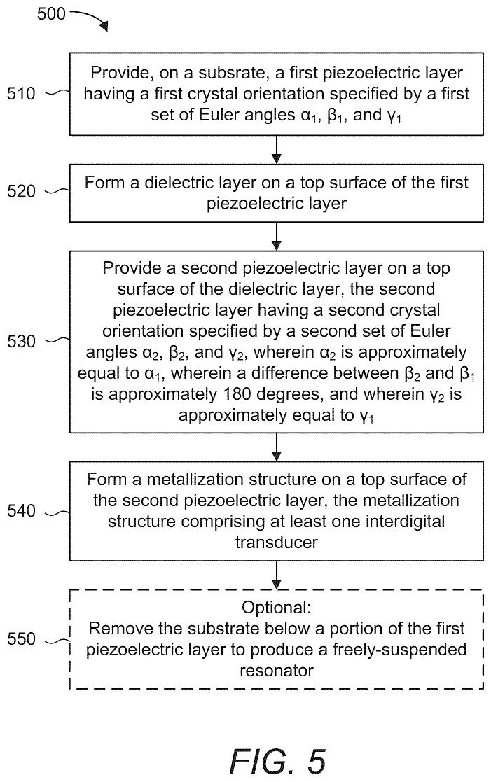

FIG. 5 is a flowchart of an example process 500 for fabricating a polarization-inverted higher-order plate-mode resonator, according to aspects of the disclosure. As shown in FIG. 5, process 500 may include, at block 510, providing, on a substrate, a first piezoelectric layer having a first crystal orientation specified by a first set of Euler angles α₁, β₁, and γ₁. As further shown in FIG. 5, process 500 may include, at block 520, forming a dielectric layer on a top surface of the first piezoelectric layer. As further shown in FIG. 5, process 500 may include, at block 530, providing a second piezoelectric layer on a top surface of the dielectric layer, the second piezoelectric layer having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁. As further shown in FIG. 5, process 500 may include, at block 540, forming a metallization structure on a top surface of the second piezoelectric layer, the metallization structure comprising at least one interdigital transducer. As further shown in FIG. 5, in some aspects, process 500 may optionally include, at block 550, removing the substrate below a portion of the first piezoelectric layer to produce a freely-suspended resonator.

In some aspects, providing the first piezoelectric layer comprises providing the first piezoelectric layer as a z-cut crystal and wherein providing the second piezoelectric layer comprises providing the second piezoelectric layer as an inverted z-cut crystal.

In some aspects, providing the first piezoelectric layer comprises providing a first piezoelectric layer having the Euler angle β1 =−180, and wherein providing the second piezoelectric layer comprises providing a second piezoelectric layer having the Euler angle β2=0.

In some aspects, providing the first piezoelectric layer comprises providing a first piezoelectric layer having the Euler angle γ1=0, and wherein providing the second piezoelectric layer comprises providing a second piezoelectric layer having the Euler angle γ2=0.

In some aspects, providing the first piezoelectric layer comprises providing a first piezoelectric layer having the Euler angle α1=90, and wherein providing the second piezoelectric layer comprises providing a second piezoelectric layer having the Euler angle α2=90.

In some aspects, providing the first piezoelectric layer comprises providing a first piezoelectric layer having Euler angles α1=90, β1=−180, and γ1=0, and wherein providing the second piezoelectric layer comprises providing a second piezoelectric layer having Euler angles α2=90, β2=0, and γ2=0.

In some aspects, at least one of the first piezoelectric layer and the second piezoelectric layer comprises lithium niobate (LiNbO3), lithium tantalate (LiTaO3), or a combination thereof.

In some aspects, the dielectric layer comprises silicon dioxide (SiO2), silicon nitride (Si3N4), or a combination thereof, with or without dopants such as fluorine, carbon, or other dopants.

Process 500 may include additional implementations, such as any single implementation or any combination of implementations described below and/or in connection with one or more other processes described elsewhere herein. Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

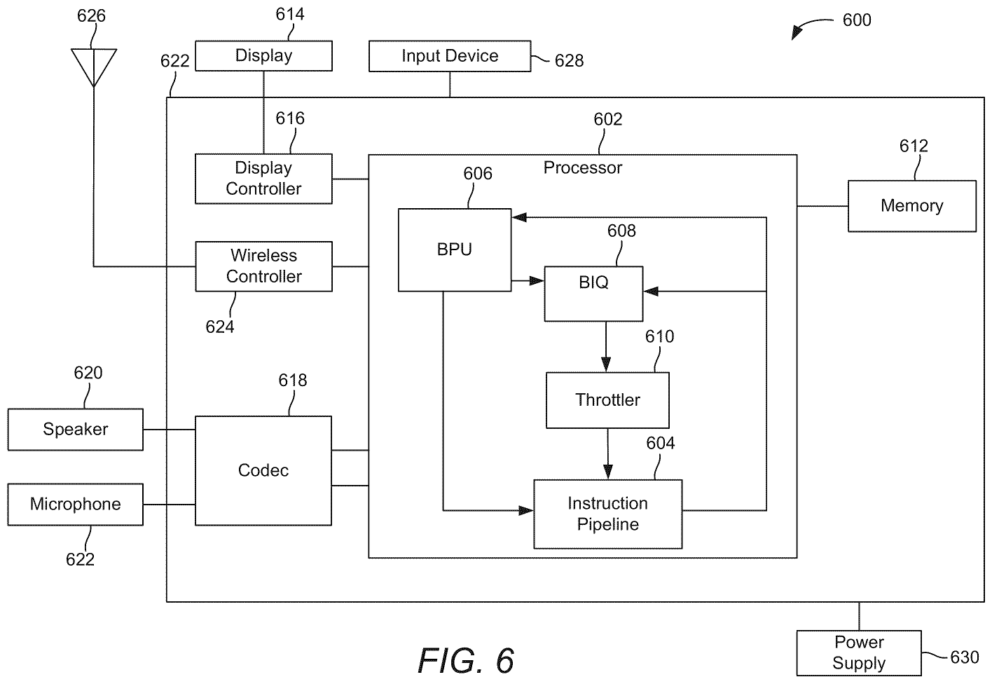

FIG. 6 illustrates an exemplary mobile device in accordance with some examples of the disclosure. Referring now to FIG. 6, a block diagram of a mobile device that is configured according to exemplary aspects is depicted and generally designated mobile device 600. In some aspects, mobile device 600 may be configured as a wireless communication device. As shown, mobile device 600 includes processor 602. Processor 602 is shown to comprise instruction pipeline 604, buffer processing unit (BPU) 606, branch instruction queue (BIQ) 608, and throttler 610 as is well known in the art. Other well-known details (e.g., counters, entries, confidence fields, weighted sum, comparator, etc.) of these blocks have been omitted from this view of processor 602 for the sake of clarity. Processor 602 may be communicatively coupled to memory 612 over a link, which may be a die-to-die or chip-to-chip link. Mobile device 600 also includes display 614 and display controller 616, with display controller 616 coupled to processor 602 and to display 614.

In some aspects, FIG. 6 may include coder/decoder (CODEC) 618 (e.g., an audio and/or voice CODEC) coupled to processor 602; speaker 620 and microphone 622 coupled to CODEC 618; and wireless controller circuits 624 (which may include a modem, radio frequency (RF) circuitry, filters, etc., which may be implemented using one or more flip-chip devices, as disclosed herein) coupled to wireless antenna 626 and to processor 602.

In a particular aspect, where one or more of the above-mentioned blocks are present, processor 602, display controller 616, memory 612, CODEC 618, and wireless controller circuits 624 can be included in a system-in-package or system-on-chip device, which may be implemented in whole or part using the techniques disclosed herein. Input device 628 (e.g., physical or virtual keyboard), power supply 630 (e.g., battery), display 614, input device 628, speaker 620, microphone 622, wireless antenna 626, and power supply 630 may be external to the system-on-chip device and may be coupled to a component of the system-on-chip device, such as an interface or a controller.

It should be noted that although FIG. 6 depicts a mobile device, the processor 602 and memory 612 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

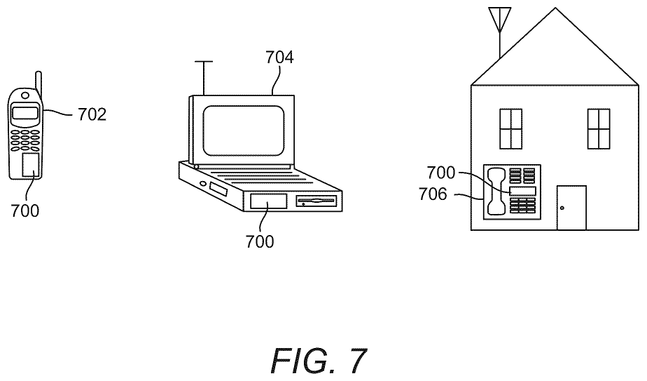

FIG. 7 illustrates various electronic devices that may be integrated with any of the aforementioned integrated device or semiconductor device in accordance with various examples of the disclosure. For example, a mobile phone device 702, a laptop computer device 704, and a fixed location terminal device 706 may each be considered generally user equipment (UE) and may include a device 700 as described herein, for example. The device may be, for example, any of the integrated circuits, dies, integrated devices, integrated device packages, integrated circuit devices, device packages, integrated circuit (IC) packages, package-on-package devices described herein. The mobile phone device 702, laptop computer device 704, and fixed location terminal device 706 illustrated in FIG. 7 are merely exemplary. Other electronic devices may also feature device including. but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

In the detailed description above it can be seen that different features are grouped together in examples. This manner of disclosure should not be understood as an intention that the example clauses have more features than are explicitly mentioned in each clause. Rather. the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A plate-mode resonator, comprising: a first piezoelectric layer having a first crystal orientation specified by a first set of Euler angles α₁, β₁, and γ₁; a dielectric layer disposed on a top surface of the first piezoelectric layer; a second piezoelectric layer, disposed on a top surface of the dielectric layer, having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁; and a metallization structure disposed on a top surface of the second piezoelectric layer, the metallization structure comprising at least one interdigital transducer.

Clause 2. The plate-mode resonator of clause 1, wherein the first piezoelectric layer, the dielectric layer, and the second piezoelectric layer resonate in a symmetric plate mode.

Clause 3. The plate-mode resonator of any of clauses 1 to 2, wherein the dielectric layer comprises silicon dioxide (SiO₂), carbon-doped silicon dioxide, fluorine-doped silicon dioxide, silicon nitride (Si₃N₄), carbon-doped silicon nitride, fluorine-doped silicon nitride, or a combination thereof.

Clause 4. The plate-mode resonator of any of clauses 1 to 3, wherein the first piezoelectric layer comprises a z-cut crystal and wherein the second piezoelectric layer comprises an inverted z-cut crystal.

Clause 5. The plate-mode resonator of any of clauses 1 to 4, wherein the first piezoelectric layer has the Euler angle β₁=−180, and wherein the second piezoelectric layer has the Euler angle β₂=0.

Clause 6. The plate-mode resonator of any of clauses 1 to 4, wherein the first piezoelectric layer has the Euler angle β₁=−148, and wherein the second piezoelectric layer has the Euler angle β₂=32.

Clause 7. The plate-mode resonator of any of clauses 1 to 6, wherein the first piezoelectric layer has the Euler angle γ₁=0, and wherein the second piezoelectric layer has the Euler angle β₂=0.

Clause 8. The plate-mode resonator of any of clauses 1 to 7, wherein the first piezoelectric layer has the Euler angle α₁=90, and wherein the second piezoelectric layer has the Euler angle α₂=90.

Clause 9. The plate-mode resonator of any of clauses 1 to 5, 7, and 8, wherein the first piezoelectric layer has the Euler angles α₁=90, β₁=−180, and γ₁=0, and wherein the second piezoelectric layer has the Euler angles α₂=90, β₂=0, and γ₂=0.

Clause 10. The plate-mode resonator of any of clauses 1 to 4 and 6 to 8, wherein the first piezoelectric layer has the Euler angles α₁=90, β₁=−148, and γ₁=0, and wherein the second piezoelectric layer has the Euler angles α₂=90, β₂=32, and γ₂=0.

Clause 11. The plate-mode resonator of any of clauses 1 to 10, wherein the first piezoelectric layer, the dielectric layer, and the second piezoelectric layer suspend over a cavity.

Clause 12. The plate-mode resonator of any of clauses 1 to 11, wherein at least one of the first piezoelectric layer and the second piezoelectric layer comprises lithium niobate (LiNbO₃), lithium tantalate (LiTaO₃), or a combination thereof.

Clause 13. A method for fabricating a plate-mode resonator, the method comprising: providing, on a substrate, a first piezoelectric layer having a first crystal orientation specified by a first set of Euler angles α1, β1, and γ1; forming a dielectric layer on a top surface of the first piezoelectric layer; providing a second piezoelectric layer on a top surface of the dielectric layer, the second piezoelectric layer having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁; and forming a metallization structure on a top surface of the second piezoelectric layer, the metallization structure comprising at least one interdigital transducer.

Clause 14. The method of clause 13, wherein the dielectric layer comprises silicon dioxide (SiO₂), carbon-doped silicon dioxide, fluorine-doped silicon dioxide, silicon nitride (Si₃N₄), carbon-doped silicon nitride, fluorine-doped silicon nitride, or a combination thereof.

Clause 15. The method of any of clauses 13 to 14, wherein providing the first piezoelectric layer comprises providing the first piezoelectric layer as a z-cut crystal and wherein providing the second piezoelectric layer comprises providing the second piezoelectric layer as an inverted z-cut crystal.

Clause 16. The method of any of clauses 13 to 15, wherein providing the first piezoelectric layer comprises providing the first piezoelectric layer having the Euler angle β₁=−180, and wherein providing the second piezoelectric layer comprises providing the second piezoelectric layer having the Euler angle β₂=0.

Clause 17. The method of any of clauses 13 to 15, wherein providing the first piezoelectric layer comprises providing the first piezoelectric layer having the Euler angle β₁=−148, and wherein providing the second piezoelectric layer comprises providing the second piezoelectric layer having the Euler angle β₂=32.

Clause 18. The method of any of clauses 13 to 17, wherein providing the first piezoelectric layer comprises providing the first piezoelectric layer having the Euler angle γ₁=0, and wherein providing the second piezoelectric layer comprises providing the second piezoelectric layer having the Euler angle γ₂=0.

Clause 19. The method of any of clauses 13 to 18, wherein providing the first piezoelectric layer comprises providing the first piezoelectric layer having the Euler angle α₁=90, and wherein providing the second piezoelectric layer comprises providing the second piezoelectric layer having the Euler angle α₂=90.

Clause 20. The method of any of clauses 13 to 16, 18, and 19, wherein providing the first piezoelectric layer comprises providing the first piezoelectric layer having the Euler angles α₁=90, β₁=−180, and γ₁=0, and wherein providing the second piezoelectric layer comprises providing the second piezoelectric layer having the Euler angles α₂=90, β₂=0, and γ₂=0.

Clause 21. The method of any of clauses 13 to 15 and 17 to 19, wherein providing the first piezoelectric layer comprises providing the first piezoelectric layer having the Euler angles α₁=90, β₁=−148, and γ₁=0, and wherein providing the second piezoelectric layer comprises providing the second piezoelectric layer having the Euler angles α₂=90, β₂=32, and γ₂=0.

Clause 22. The method of any of clauses 13 to 21, wherein at least one of the first piezoelectric layer and the second piezoelectric layer comprises lithium niobate (LiNbO₃), lithium tantalate (LiTaO₃), or a combination thereof.

Clause 23. The method of any of clauses 13 to 22, further comprising removing the substrate below a portion of the first piezoelectric layer.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A plate-mode resonator, comprising:
a first piezoelectric layer having a first crystal orientation specified by a first set of Euler angles α₁, β₁, and γ₁;
a dielectric layer disposed on a top surface of the first piezoelectric layer;
a second piezoelectric layer, disposed on a top surface of the dielectric layer, having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁; and
a metallization structure disposed on a top surface of the second piezoelectric layer, the metallization structure comprising at least one interdigital transducer.

2. The plate-mode resonator of claim 1, wherein the first piezoelectric layer, the dielectric layer, and the second piezoelectric layer resonate in a symmetric plate mode.

3. The plate-mode resonator of claim 1, wherein the first piezoelectric layer comprises a z-cut crystal and wherein the second piezoelectric layer comprises an inverted z-cut crystal.

4. The plate-mode resonator of claim 1, wherein the first piezoelectric layer has the Euler angle β₁=−180, and wherein the second piezoelectric layer has the Euler angle β₂=0.

5. The plate-mode resonator of claim 1, wherein the first piezoelectric layer has the Euler angle β₁=−148, and wherein the second piezoelectric layer has the Euler angle β₂=32.

6. The plate-mode resonator of claim 1, wherein the first piezoelectric layer has the Euler angle γ₁=0, and wherein the second piezoelectric layer has the Euler angle γ₂=0.

7. The plate-mode resonator of claim 1, wherein the first piezoelectric layer has the Euler angle α₁=90, and wherein the second piezoelectric layer has the Euler angle β₂=90.

8. The plate-mode resonator of claim 1, wherein the first piezoelectric layer has the Euler angles α₁=90, β₁=−180, and γ₁=0, and wherein the second piezoelectric layer has the Euler angles α₂=90, β₂=0, and γ₂=0.

9. The plate-mode resonator of claim 1, wherein the first piezoelectric layer has the Euler angles α₁=90, β₁=−148, and γ₁=0, and wherein the second piezoelectric layer has the Euler angles α₂=90, β₂=32, and γ₂=0.

10. The plate-mode resonator of claim 1, wherein the dielectric layer comprises silicon dioxide (SiO₂), carbon-doped silicon dioxide, fluorine-doped silicon dioxide, silicon nitride (Si₃N₄), carbon-doped silicon nitride, fluorine-doped silicon nitride, or a combination thereof.

11. The plate-mode resonator of claim 1, wherein at least one of the first piezoelectric layer and the second piezoelectric layer comprises lithium niobate (LiNbO₃), lithium tantalate (LiTaO₃), or a combination thereof.

12. The plate-mode resonator of claim 1, wherein the first piezoelectric layer, the dielectric layer, and the second piezoelectric layer suspend over a cavity.

13. A method for fabricating a plate-mode resonator, the method comprising:
providing, on a substrate, a first piezoelectric layer having a first crystal orientation specified by a first set of Euler angles α₁, β₁, and γ₁;
forming a dielectric layer on a top surface of the first piezoelectric layer;
providing a second piezoelectric layer on a top surface of the dielectric layer, the second piezoelectric layer having a second crystal orientation specified by a second set of Euler angles α₂, β₂, and γ₂, wherein α₂ is approximately equal to α₁, wherein a difference between β₂ and β₁ is approximately 180 degrees, and wherein γ₂ is approximately equal to γ₁; and
forming a metallization structure on a top surface of the second piezoelectric layer, the metallization structure comprising at least one interdigital transducer.

14. The method of claim 13, wherein providing the first piezoelectric layer comprises providing the first piezoelectric layer as a z-cut crystal and wherein providing the second piezoelectric layer comprises providing the second piezoelectric layer as an inverted z-cut crystal.

15. The method of claim 13, wherein providing the first piezoelectric layer comprises providing the first piezoelectric layer having the Euler angle β₁=−180, and wherein providing the second piezoelectric layer comprises providing the second piezoelectric layer having the Euler angle β₂=0.

16. The method of claim 13, wherein providing the first piezoelectric layer comprises providing the first piezoelectric layer having the Euler angle β₁=−148, and wherein providing the second piezoelectric layer comprises providing the second piezoelectric layer having the Euler angle β₂=32.

17. The method of claim 13, wherein providing the first piezoelectric layer comprises providing the first piezoelectric layer having the Euler angle γ₁=0, and wherein providing the second piezoelectric layer comprises providing the second piezoelectric layer having the Euler angle γ₂=0.

18. The method of claim 13, wherein providing the first piezoelectric layer comprises providing the first piezoelectric layer having the Euler angle α₁=90, and wherein providing the second piezoelectric layer comprises providing the second piezoelectric layer having the Euler angle α₂=90.

19. The method of claim 13, wherein providing the first piezoelectric layer comprises providing the first piezoelectric layer having the Euler angles α₁=90, β₁=−180, and γ₁=0, and wherein providing the second piezoelectric layer comprises providing the second piezoelectric layer having the Euler angles α₂=90, β₂=0, and γ₂=0.

20. The method of claim 13, wherein providing the first piezoelectric layer comprises providing the first piezoelectric layer having the Euler angles α₁=90, β₁=−148, and γ₁=0, and wherein providing the second piezoelectric layer comprises providing the second piezoelectric layer having the Euler angles α₂=90, β₂=32, and γ₂=0.

21. The method of claim 13, wherein the dielectric layer comprises silicon dioxide (SiO₂), carbon-doped silicon dioxide, fluorine-doped silicon dioxide, silicon nitride (Si₃N₄), carbon-doped silicon nitride, fluorine-doped silicon nitride, or a combination thereof.

22. The method of claim 13, wherein at least one of the first piezoelectric layer and the second piezoelectric layer comprises lithium niobate (LiNbO₃), lithium tantalate (LiTaO₃), or a combination thereof.

23. The method of claim 13, further comprising removing the substrate below a portion of the first piezoelectric layer.
